(19) United States
(12) Patent Application Publication
(10) Pub. No.: US 2006/0169199 A1
(43) Pub. Date: Aug. 3, 2006

(54) Crystallization and purification of macrolides

(76) Inventors: Vilmos Keri, Debrecen (HU); Istvan Melczer, Debrecen (HU); Adrienne Kovacsne-Mezei, Debrecen (HU); Andrea Csorvasi, Debrecen (HU)

Correspondence Address: KENYON & KENYON LLP, ONE BROADWAY, NEW YORK, NY, 10004, US

(21) Appl. No.: 11/326,723

(22) Filed: Jan. 5, 2006

Related U.S. Application Data
(63) Continuation-in-part of application No. 10/815,339, filed on Mar. 31, 2004.
(63) Continuation-in-part of application No. 11/293,353, filed on Dec. 1, 2005.
(63) Continuation-in-part of application No. 11/293,747, filed on Dec. 1, 2005.
(60) Provisional application No. 60/512,887, filed on Oct. 20, 2003.
(60) Provisional application No. 60/461,707, filed on Apr. 9, 2003.
(60) Provisional application No. 60/459,591, filed on Mar. 31, 2003.
(60) Provisional application No. 60/632,372, filed on Dec. 1, 2004.
(60) Provisional application No. 60/633,926, filed on Dec. 6, 2004.
(60) Provisional application No. 60/641,697, filed on Jan. 5, 2005.
(60) Provisional application No. 60/641,868, filed on Jan. 5, 2005.
(60) Provisional application No. 60/641,869, filed on Jan. 5, 2005.
(60) Provisional application No. 60/662,440, filed on Mar. 16, 2005.
(60) Provisional application No. 60/705,681, filed on Aug. 3, 2005.
(60) Provisional application No. 60/709,160, filed on Aug. 17, 2005.
(60) Provisional application No. 60/632,372, filed on Dec. 1, 2004.
(60) Provisional application No. 60/633,926, filed on Dec. 6, 2004.
(60) Provisional application No. 60/641,697, filed on Jan. 5, 2005.
(60) Provisional application No. 60/641,868, filed on Jan. 5, 2005.
(60) Provisional application No. 60/641,869, filed on Jan. 5, 2005.
(60) Provisional application No. 60/662,440, filed on Mar. 16, 2005.
(60) Provisional application No. 60/705,681, filed on Aug. 3, 2005.
(60) Provisional application No. 60/709,160, filed on Aug. 17, 2005.

(51) Int. Cl. C30B 15/00; C30B 21/06; C30B 27/02; C30B 28/10; C30B 30/04

(52) U.S. Cl. 117/23

(57) ABSTRACT

The invention provides a method for crystallization and purification of tacrolimus that includes the step of providing a combination of a macrolide and a polar solvent, dopolar aprotic solvent, or hydrocarbon solvent at pH of 7 or above. The invention also provides a novel crystalline form of tacrolimus.

### RELATED APPLICATIONS

This application is a continuation-in-part of U.S. patent application Ser. No. 10/815,339, filed Mar. 31, 2004, which claims benefit to U.S. Provisional Patent Application Nos. 60/512,887, filed Oct. 20, 2003, 60/461,707, filed Apr. 9, 2003, and 60/459,591, filed Mar. 31, 2003, the contents of all of which are incorporated by reference herein in their entirety. This application is also a continuation-in-part of U.S. patent application Ser. No. 11/293,353, filed Dec. 1, 2005, which claims benefit of U.S. Provisional Patent Applications Nos. 60/632,372, filed Dec. 1, 2004, 60/633,926, filed Dec. 6, 2004, 60/641,697, filed Jan. 5, 2005, 60/641,868, filed Jan. 5, 2005, 60/641,869, filed Jan. 5, 2005, 60/662,440, filed Mar. 16, 2005, 60/705,681, filed Aug. 3, 2005, and 60/709,160, filed Aug. 17, 2005, the contents of which are incorporated herein in their entirety by reference. This application is also a continuation-in-part of U.S. patent application Ser. No. 11/293,747, filed Dec. 1, 2005, which claims benefit of U.S. Provisional Patent Applications Nos. 60/632,372, filed Dec. 1, 2004, 60/633,926, filed Dec. 6, 2004, 60/641,697, filed Jan. 5, 2005, 60/641,868, filed Jan. 5, 2005, 60/641,869, filed Jan. 5, 2005, 60/662,440, filed Mar. 16, 2005, 60/705,681, filed Aug. 3, 2005, and 60/709,160, filed Aug. 17, 2005, the contents of which are incorporated herein in their entirety by reference.

### FIELD OF THE INVENTION

The present invention relates to the crystallization and purification of macrolides, especially tacrolimus, sirolimus (rapamycin), pimecrolimus, and everolimus.

### BACKGROUND OF THE INVENTION

Macrolides are multi-membered lactone rings having one or more deoxy sugars as substituents. Erythromycin, azithromycin, and clarithromycin are macrolides that have bacteriostatic and/or bactericidal activity. Ascomycin, tacrolimus, and Pimecrolimus are also macrolides.

Ascomycin is an immunomodulating macrolactam that reportedly blocks T-cell activation, inhibits cytokine release, and inhibits mast cell activation. “The mechanism of action of ascomycin is very similar to that of cyclosporin and of tacrolimus, although the three compounds have different chemical structures.” C. E. Griffiths, Ascomycin: An Advance in the Management of Atopic Dermatitis. 144 Br. J. Dermatol., U.S. Pat. No. 4,679,679 (April 2001). Ascomycin is disclosed in U.S. Pat. No. 3,244,592, which describes the compound as an antifungal agent. The use of ascomycin as an immunosuppressant is disclosed in European Patent Application No. 323865.

Tacrolimus (FK 506) is a macrolide antibiotic that is also an immunosuppressive agent. More potent than cyclosporin, tacrolimus has a selective inhibitory effect on T-lymphocytes.

Rapamycin is an immunosuppressive lactam macrolide produceable, for example by Streptomyces hygroscopicus. The structure of rapamycin is given in Kesseler, H., et al.; 1993; Helv. Chim. Acta; 76:117. Rapamycin is an extremely potent immunosuppressant, and has also been shown to have antitumor and antifungal activity. Its utility as a pharmaceutical, however, is restricted by its very low and variable bioavailability. Moreover, rapamycin is highly insoluble in aqueous media, e.g. water, making it difficult to formulate stable galenic compositions. Numerous derivatives of rapamycin are known. Rapamycin and its structurally similar analogues and derivatives are termed collectively herein as “rapamycins”. On oral administration to humans, solid rapamycins, e.g. rapamycin, may not be absorbed to any significant extent into the bloodstream.

Pimecrolimus is an anti-inflammatory compound derived from ascomycin, which is produced by certain strains of Streptomyces. Pimecrolimus is sold in the United States under the brand name ELIDEL®, and is approved for use against atopic dermatitis. The systematic name of Pimecrolimus is (1R,9S,12S,13R,14S,17R,18E,21S,23S,24R,25S,27R)-12-[(1E)-2-{(1R,3R,4S)-4-chloro-3-methoxycyclohexyl}-1-methylvinyl]-17-ethyl-1,14-dihydroxy-23,25-dimethoxy-13,19,21,27-tetramethyl-11,28-dioxa-4-aza-tricyclo[22.3.1.0^{4,9}]octacos-18-ene-2,3,10,16-tetraone. Pimecrolimus is the 32-epichloro derivative of ascomycin. Its empirical formula is C₄₃H₆₈ClNO₁₁, and its molecular weight is 810.47.

The crystalline form of a solid chemical compound (or the lack of a crystalline form) affects many of the compound's properties that are important with respect to formulation as a pharmaceutical. Such properties include, for example, the flowability of the milled solid. Flowability affects the ease with which the material is handled during processing into a pharmaceutical product. When particles of the powdered compound do not flow past each other easily, a formulation specialist must take that fact into account in developing a tablet or capsule formulation, which may necessitate the use of glidants such as colloidal silicon dioxide, talc, starch, or tribasic calcium phosphate.

Another important property of a pharmaceutical compound that may depend on crystallinity is its rate of dissolution in aqueous fluid. The rate of dissolution of an active ingredient in a patient's stomach fluid can have therapeutic consequences since it imposes an upper limit on the rate at which an orally-administered active ingredient can reach the patient's bloodstream. The solid state form of a compound may also affect its behavior on compaction and its storage stability.

These practical physical characteristics are influenced by the conformation and orientation of molecules in the unit cell, which defines a particular crystalline form of a substance. These conformational and orientation factors in turn result in particular intramolecular interactions such that different crystalline forms may give rise to distinct spectroscopic properties that may be detectable by such analytical techniques as powder X-ray diffraction, solid state ¹³C NMR spectrometry, and infrared spectrometry. A particular crystalline form may also give rise to thermal behavior different from that of the amorphous material or another crystalline form. Thermal behavior is measured in the laboratory by such techniques as capillary melting point, thermogravimetric analysis (TGA), and differential scanning calorimetry (DSC), and can be used to distinguish some crystalline forms from others.

The crystalline form of a solid chemical compound (or the lack of a crystalline form) affects many of the compound's properties that are important with respect to formulation as a pharmaceutical. Such properties include, for example, the flowability of the milled solid. Flowability affects the ease with which the material is handled during processing into a pharmaceutical product. When particles of the powdered compound do not flow past each other easily, a formulation specialist must take that fact into account in developing a tablet or capsule formulation, which may necessitate the use of glidants such as colloidal silicon dioxide, talc, starch or tribasic calcium phosphate.

Another important property of a pharmaceutical compound that may depend on crystallinity is its rate of dissolution in aqueous fluid. The rate of dissolution of an active ingredient in a patient's stomach fluid can have therapeutic consequences since it imposes an upper limit on the rate at which an orally-administered active ingredient can reach the patient's bloodstream. The solid state form of a compound may also affect its behavior on compaction and its storage stability.

The discovery of new crystalline forms of a pharmaceutically useful compound provides a new opportunity to improve the performance characteristics of a pharmaceutical product. It enlarges the repertoire of materials that a formulation scientist has available for designing, for example, a pharmaceutical dosage form of a drug with a targeted release profile or other desired characteristic.

### SUMMARY OF THE INVENTION

The present invention relates to a method for crystallization and purification of macrolides, especially tacrolimus, sirolimus, pimecrolimus, and everolimus, including the steps of providing a combination of a macrolide starting material; a polar solvent, especially a polar solvent that is an alkyl ester of an alkanoic acid, an alcohol, an ether, an aliphatic ketone, an aliphatic nitrile, or a dipolar aprotic solvent; a hydrocarbon solvent, especially an acyclic or cyclic aliphatic hydrocarbon or an aromatic hydrocarbon (e.g. toluene); and water; at a pH of about 7 or above, especially about 8 or above; maintaining the combination at a temperature of between about −15° C. to about 50° C., preferably between about −5° C. to about 40° C., most preferably between about −2° C. to about 35° C. for at least about 1 hour, preferably between about 48 to about 100 hours; and isolating crystalline macrolide.

In another aspect, the crystalline macrolide obtained by the process described above is a crystalline form of tacrolimus characterized by powder X-ray diffraction having peaks at about 10.5, 11.3 and 13.8±0.2 degrees 2θ.

In another aspect, the present invention relates to a method for crystallization and purification of a macrolide, especially tacrolimus, sirolimus, pimecrolimus, or everolimus including the steps of providing a concentrate residue from whole-broth extraction of macrolide-containing biomatter in a polar solvent, especially a polar solvent that is an alkyl ester of an alkanoic acid, an alcohol, an ether, an aliphatic ketone, an aliphatic nitrile, or a dipolar aprotic solvent; combining the solution, in any order, with water and a hydrocarbon solvent, especially an acyclic or cyclic aliphatic hydrocarbon or an aromatic hydrocarbon (e.g. toluene), wherein the pH is about 7 or above, especially about 8 or above; maintaining the combination at a crystallization temperature for a crystallization time; and isolating crystalline macrolide.

In another aspect, the crystalline macrolide obtained by the process described above is a crystalline form of tacrolimus characterized by powder X-ray diffraction having peaks at about 10.5, 11.3 and 13.8±0.2 degrees 2θ.

In a further aspect, the present invention relates to a method of crystallizing and purifying a macrolide, especially tacrolimus, sirolimus, pimecrolimus, or everolimus including the steps of combining, in any order, an oil that is a concentrate obtained by concentrating a solution obtained by extracting macrolide-containing biomatter with a hydrophobic extraction solvent, e.g. butyl acetate; with a polar solvent, especially a polar solvent that is an alkyl ester of an alkanoic acid, an alcohol, an ether, an aliphatic ketone, an aliphatic nitrile, or a dipolar aprotic solvent; a hydrocarbon solvent, especially an acyclic or cyclic aliphatic hydrocarbon or an aromatic hydrocarbon (e.g. toluene); and water; wherein the pH is about 7 or above, especially 8 or above; maintaining the combination at a first crystallization temperature for a first crystallization time; and isolating crystalline macrolide.

In another aspect, the crystalline macrolide obtained by the process described above is a crystalline form of tacrolimus characterized by powder X-ray diffraction having peaks at about 10.5, 11.3 and 13.8±0.2 degrees 2θ.

In any of the forgoing aspects, the combination can be, but need not be, maintained at a second crystallization temperature for a second crystallization time.

In one embodiment, the present invention provides crystalline tacrolimus.

In another embodiment, the present invention provides a crystalline form of tacrolimus characterized by powder X-ray diffraction having peaks at about 10.5, 11.3 and 13.8±0.2 degrees 2θ.

### BRIEF DESCRIPTION OF THE DRAWINGS

FIG. 1 illustrates a powder X-Ray Diffraction pattern of crystalline Tacrolimus according to example 4;

FIG. 2 illustrates a powder X-Ray Diffraction pattern of crystalline Tacrolimus according to example 5;

FIG. 3 illustrates a powder X-Ray Diffraction pattern of crystalline Tacrolimus according to example 6;

FIG. 4 illustrates a TGA curve of crystalline Tacrolimus according to example 6;

FIG. 5 illustrates a powder X-Ray Diffraction pattern of crystalline Tacrolimus according to example 7;

FIG. 6 illustrates a TGA curve of crystalline Tacrolimus according to example 7;

FIG. 7 illustrates a powder X-Ray Diffraction pattern of crystalline Tacrolimus according to example 8;

FIG. 8 illustrates a TGA curve of crystalline Tacrolimus according to example 8;

FIG. 9 illustrates a powder X-Ray Diffraction pattern of crystalline Tacrolimus according to example 9; and

FIG. 10 illustrates a TGA curve of crystalline Tacrolimus according to example 9.

### DETAILED DESCRIPTION OF THE INVENTION

As used herein in connection with a measured quantity, “about” refers to that variation in the measured quantity as would be expected by the skilled artisan performing or interpreting the measurement and exercising a level of care commensurate with the objective of the measurement and the precision of the measuring equipment being used.

As used herein, ambient temperature refers to a temperature of about 18° C. to about 25° C.

As used herein, “RN” refers to the registry number assigned to a chemical compound by the Chemical Abstracts Service, Columbus Ohio, USA).

The method of the present invention is applied to the crystallization and purification of macrolides from macrolide-containing starting material. The macrolides are multi-membered lactone rings having one or more deoxy sugars as substituents. Erythromycin, azithromycin, and clarithromycin are macrolides that have bacteriostatic and/or bactericidal activity. The macrolides tacrolimus (FK 506) and sirolimus (rapamycin) are preferred macrolides for use in the practice of the present invention. The macrolides pimecrolimus (the 33-epichloro derivative of ascomycin; RN=137071-32-0) and everolimus (40-O-(2-hydroxyethyl)-rapamycin; RN=159351-69-6) are also preferred macrolides for use in the practice of the present invention.

The macrolides are typically obtained by fermentation, although synthetic routes to some are known. The macrolide starting material for use in the practice of the present invention can be from any source. Concentrate residue, obtained by concentrating the extract of the entire fermentation broth (“whole broth method”) from macrolide-containing biomatter, can be used as the macrolide starting material for the present method. Use of hydrophobic extraction solvent in the extraction to obtain the solution to be concentrated results in an efficient extraction yield, leaving behind most water-soluble impurities, with the removal of mycelium in one step. Concentration under reduced pressure at T>25° C. results in a high evaporation rate of solvent without precipitation or decomposition of the macrolide, and provides a macrolide starting material for use in the practice of the present invention. Concentrate residue for use as macrolide starting material in the practice of the present invention can be obtained as described in U.S. patent application Ser. No. 10/366,266, published as U.S. 2003/01666924 A1 and incorporated herein in its entirety by reference.

Oily residue from macrolide-producing processes can also be used as starting macrolide starting material.

Preferred macrolide-containing biomatter that can be a source of macrolide starting material for the practice of the present invention includes tacrolimus-containing biomatter, particularly fermentation broth obtainable by fermentation using a tacrolimus-producing microorganism, for example, Streptomyces tsukubaensis, new and mutated strains thereof, Streptomyces hygroscopicus, and Streptomyces lividans, as described in U.S. Pat. Nos. 4,894,366, 5,116,756, 5,624,842, 5,496,727, and 5,622,866, all of which are incorporated herein by reference. Sirolimus-containing (rapamycin-containing) biomatter is also a preferred macrolide-containing biomatter. Sirolimus (rapamycin) can be produced by fermentation of Streptomyces hygroscopicus, NRRL 5491, as described in U.S. Pat. No. 3,993,749, incorporated herein by reference. Pimecrolimus-containing biomatter and everolimus-containing biomatter are also examples of preferred macrolide-containing biomatter for use in the practice of the method of the present invention. Ascomycin-containing biomatter is also a preferred macrolide-containing biomatter for use in the practice of the present invention

The method of the present invention employs, among other things, polar solvents, hydrocarbon solvents, and bases (alkali).

Polar solvents are organic compounds, normally liquid at ambient temperature, that dissolve a macrolide, especially tacrolimus, sirolimus, pimecrolimus, or everolimus. Polar solvents useful in the practice of the present invention include esters, alcohols, aliphatic nitriles, acyclic and cyclic aliphatic ethers, aliphatic ketones, and dipolar aprotic solvents.

Esters useful in the practice of the present invention have the general formula R₁—C(O)O—R₂, wherein R₁ is H or linear or branched C1-6 alkyl, and R₂ is linear or branched C1-6 alkyl. Examples of esters include methyl acetate, ethyl acetate, n-propyl acetate, iso-propyl acetate, n-butyl acetate, iso-butyl acetate, methyl formate, n-propyl formate, iso-propyl formate, n-butyl formate, and iso-butyl formate, to mention just a few. Alcohols (alkanols, glycols, and aromatic alcohols) useful in the practice of the present invention include methanol, ethanol, n-propanol, iso-propanol, ethylene glycol, propylene glycol, polyethylene glycol, polypropylene glycol, amyl alcohol and benzyl alcohol, to mention just a few.

Aliphatic ketones useful in the practice of the present invention have the general formula R₁—C(O)—R₂, wherein R₁ and R₂ are, independently, linear or branched alkyl groups, each having from 1 to 4 carbon atoms. Examples of aliphatic ketones include acetone, methyl ethyl ketone, and methyl iso-butyl ketone, to mention just three.

Examples of aliphatic nitriles useful in the practice of the present invention include acetonitrile, propionitrile, and butyronitrile, to mention just three.

Ethers useful in the practice of the present invention include both acyclic and cyclic aliphatic ethers. Acyclic aliphatic ethers have the general formula R₁—O—R₂, wherein R₁ and R₂ are as defined above. Examples of acyclic aliphatic ethers include diethyl ether, di-n-propyl ether, and ethyl n-propyl ether, to mention just a few. Tetrahydrofuran and the dioxanes are examples of cyclic aliphatic ethers useful in the practice of the present invention.

Dipolar aprotic solvents are well known to the skilled artisan. Dimethyl acetamide (DMAC), dimethyl formamide (DMF), N-methyl-2-pyrrolidone (NMP), acatamide, dioxane and dioxalane are examples of dipolar aprotic solvents useful in the practice of the present invention.

Hydrocarbon solvents are organic compounds, normally liquid at ambient temperature, that are poor solvents for macrolides. The hydrocarbon solvents can be aliphatic hydrocarbon solvents, or they can be aromatic hydrocarbon solvents.

The aliphatic hydrocarbon solvents can be acyclic or they can be cyclic. Acyclic hydrocarbon solvents can be linear or branched and have the general formula CₙH₂ₙ₊₂, where n is from about 5 to about 10. n-Hexane, n-heptane, octane and iso-octane are examples of preferred acyclic aliphatic hydrocarbon solvents. Cyclohexane and methylcyclohexane are examples of cyclic aliphatic hydrocarbon solvents. Examples of aromatic hydrocarbon solvents include benzene, toluene, the xylenes, and the tetralins, to mention just a few.

Any base, organic or inorganic, can be used in the practice of the present invention. Examples of inorganic bases include ammonia, alkali and alkaline earth metal hydroxides, bicarbonates, and carbonates, to mention just a few. The amines are examples of organic bases that can be used in the practice of the present invention.

In another aspect, the crystalline macrolide obtained by the process described above is a crystalline form of tacrolimus characterized by powder X-ray diffraction having peaks at about 10.5, 11.3 and 13.8±0.2 degrees 2θ.

The present invention provides a method for crystallization and purification of a macrolide, preferably tacrolimus, sirolimus, pimecrolimus, or everolimus including the steps of providing, in a crystallization vessel, a combination of a macrolide starting material, a polar solvent, a hydrocarbon solvent, and water, whereby a water rich phase is formed. A water-rich phase is a phase in with the majority of the solvent is water and can contain other solvents and solutes. The pH of the water-rich phase is or is adjusted to be about 7 or above, preferably about 8 or above. The pH can be adjusted by addition of base.

The combination is provided, preferably with agitation, and is maintained at a temperature of between about −15° C. to about 50° C., preferably between about −5° C. to about 40° C., most preferably between about −2° C. to about 35° C. for at least about 1 hour, preferably between about 48 to about 100 hours, whereby a macrolide-rich phase forms.

The manner in which the provided combination is assembled is irrelevant to the practice of the present invention. The components of the combination can be assembled in any order, or they can be assembled simultaneously.

The combination of macrolide, polar solvent, hydrocarbon solvent, and water is provided in a crystallization vessel (crystallization space) provided with an agitator. The design and peculiar characteristics of the crystallization vessel are unimportant and the skilled artisan will know to select the crystallization vessel and agitator based on, among other things, the volume of the combination and the process variables.

At the start of the first crystallization time, the combination provided will include two or more phases, at least one of which is water-rich. The pH of the water-rich phase is about 7 or above, preferably about 8 or above. The pH of the water-rich phase can be constant throughout the total crystallization time, or it can be varied in the course of the crystallization time, provided the pH is always at least about 7 or above.

The desired pH is established with the use of any available inorganic or organic base and the desired pH can be established in any manner or sequence. For example, the pH of the water used to assemble the combination can be adjusted, prior to assembly of the combination, with an inorganic or organic base. Thus, as used herein in connection with the combination provided, “water” will be understood to include dilute aqueous solutions (water solutions) of inorganic or organic bases, e.g., N/10 NaOH_{aq}, N/10 KOH, N/10 Ca(OH)₂, N/10 NH_{3aq}, N/₁₀ (C₂H₅)₃N_{aq}, N/10 diethylamine or triethy amine, N/10 pyridine etc. Base can be added before the water-rich phase is established by, for example, admitting a low-boiling amine, e.g. methylamine, before water is introduced. The skilled artisan will recognize a plethora of alternatives to establishing the desired pH of the water-rich phase.

The pH can be adjusted after the combination is assembled by adding inorganic base, neat, especially as a gas, or in solution in a suitable solvent, e.g. water. The pH can be adjusted in increments. For example, the pH of the water used to assemble the combination can be adjusted to, e.g., ca. 7 before the combination is assembled, and, after assembly, the pH of the water-rich phase can be further adjusted, e.g. to pH 8, by the addition of base, neat or in solution.

During the course of the total crystallization time, at least one macrolide-rich phase develops, from which the macrolide crystallizes, substantially free of impurities. At the end of the total crystallization time, crystalline macrolide is isolated by any of the common methods, for example filtration (gravity or pressure-assisted) or centrifugation, to mention just two. The purity of the isolated crystalline macrolide rivals that of macrolide purified by multiple-pass chromatography.

In one embodiment, the combination provided is assembled by the steps of providing macrolide starting material that is a solution of macrolide, or a concentrate from macrolide extraction, preferably tacrolimus, sirolimus, pimecrolimus, or everolimus in a polar solvent and combining the solution, in any order, with hydrocarbon solvent and water.

The solution provided can be made by any means or method. The concentration of the solution provided is not critical and will generally be between about 0.05 g/ml (g macrolide per ml polar solvent) and about 0.3 g/ml. The macrolide can come from any source and can be a solid, semi-solid, or an oil (especially an oil that is a residue from concentration of extract from a whole-broth extraction of macrolide-containing biomatter).

The relative volumes of solution, water, and hydrocarbon solvent are not critical. Typically, the ratio of the volume of solution to the volume of hydrocarbon solvent will be between about 1:2 and about 1: 10. The ratio of the volume of solution to the volume of water will typically be between about 1:8 to about 1:25.

The pH of the water-rich phase can be adjusted and the combination treated as described above.

In another embodiment, the combination provided is assembled by combining, in any order, macrolide starting material, preferably tacrolimus, sirolimus, pimecrolimus, or everolimus starting material, hydrocarbon solvent, polar solvent, and water, wherein the tacrolimus starting material is an oily phase that is a concentrate obtained by concentrating a solution obtained by extracting macrolide-containing biomatter with a hydrophobic extraction solvent, especially wherein the hydrophobic extraction solvent is selected from the group consisting of C2-C6 linear and branched esters of acetic acid or formic acid, C3-C6 linear or branched aliphatic ketones, halogenated methanes, and aromatic hydrocarbons that are liquid at 25° C., and that have a boiling point at atmospheric pressure less than about 150° C., wherein the extraction is at a temperature between about 2° C. to about 70° C., especially between about 30° C. and about 70° C., and at a pH of between about 5.5 and about 13, especially between about 7.5 and about 13, to obtain the solution of the macrolide in the hydrophobic extraction solvent.

The oil (macrolide starting material) can first be combined with polar solvent or hydrocarbon solvent or water. The order is irrelevant to the practice of the present invention. The base required to establish the desired pH can be introduced at any point, or at several points prior to or during the crystallization time. The base can be introduced neat, or as a solution, e.g. a solution in water.

In another aspect, the crystalline macrolide obtained by the process described above is a crystalline form of tacrolimus characterized by powder X-ray diffraction having peaks at about 10.5, 11.3 and 13.8±0.2 degrees 2θ.

In one embodiment, the present invention provides crystalline tacrolimus.

In another embodiment, the present invention provides a crystalline form of tacrolimus characterized by powder X-ray diffraction having peaks at about 10.5, 11.3 and 13.8±0.2 degrees 2θ. The crystalline form may be a monohydrate. The crystalline form of tacrolimus may be further characterized by a XRD having an additional peak at about: 14.2±0.2 degrees 2θ. The crystalline form of tacrolimus may be even further characterized by a XRD having additional peaks at about: 8.7, 15.4 and 19.1±0.2 degrees 2θ.

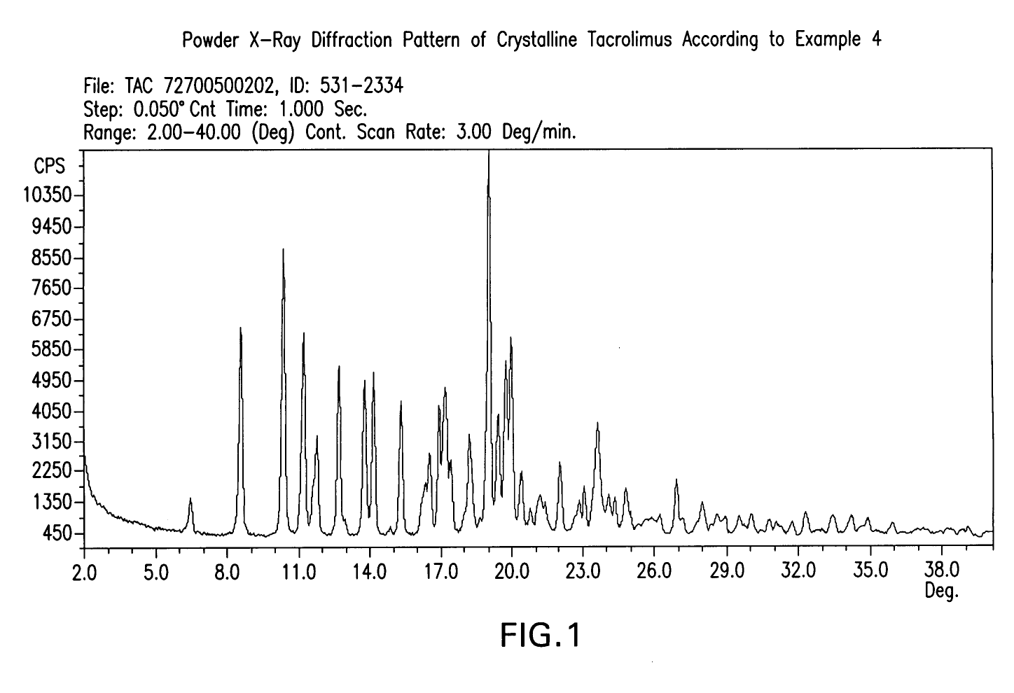

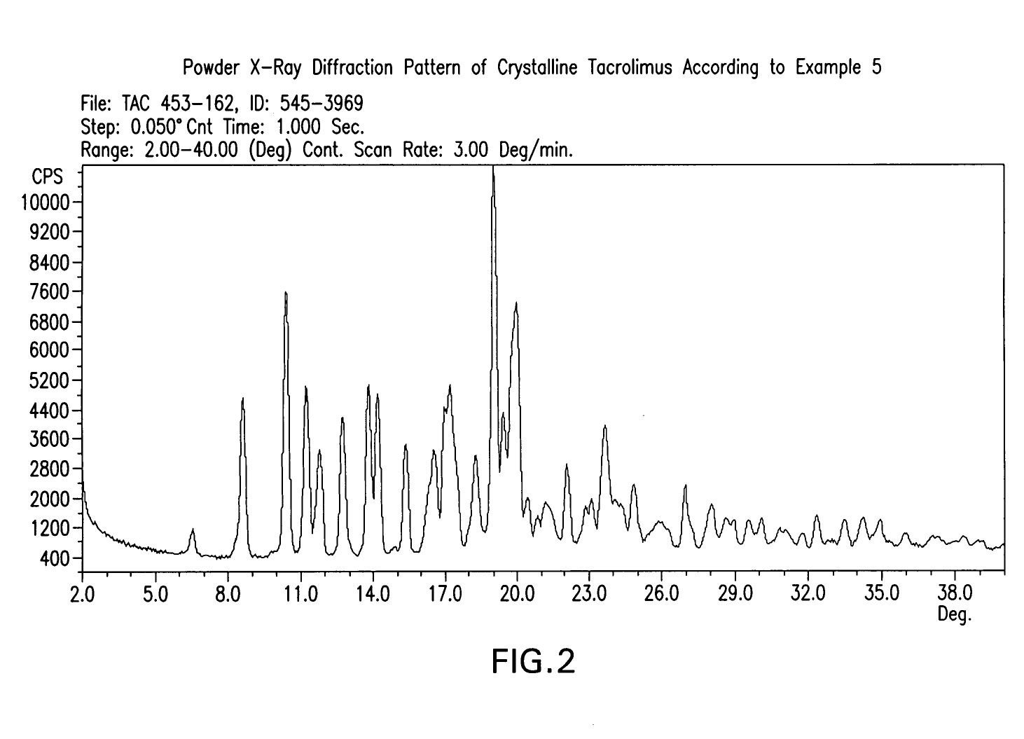

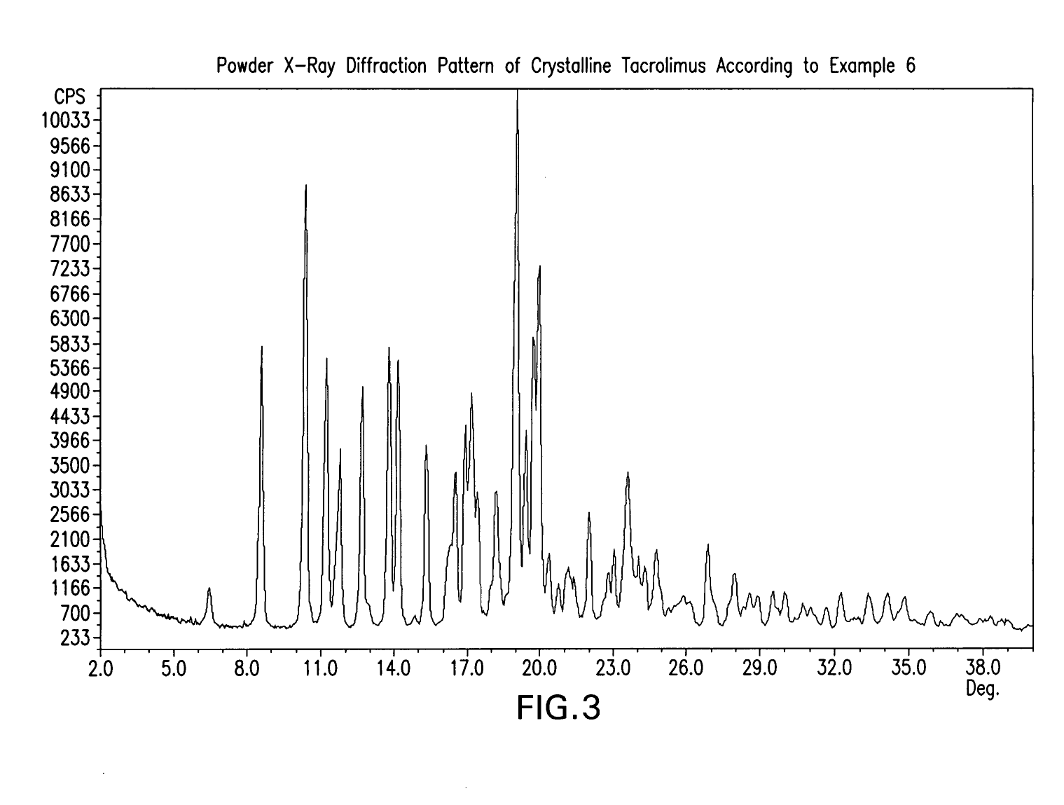

The PXRD patterns of the crystalline form of tacrolimus are substantially depicted in FIGS. 1, 2, 3, and 4.

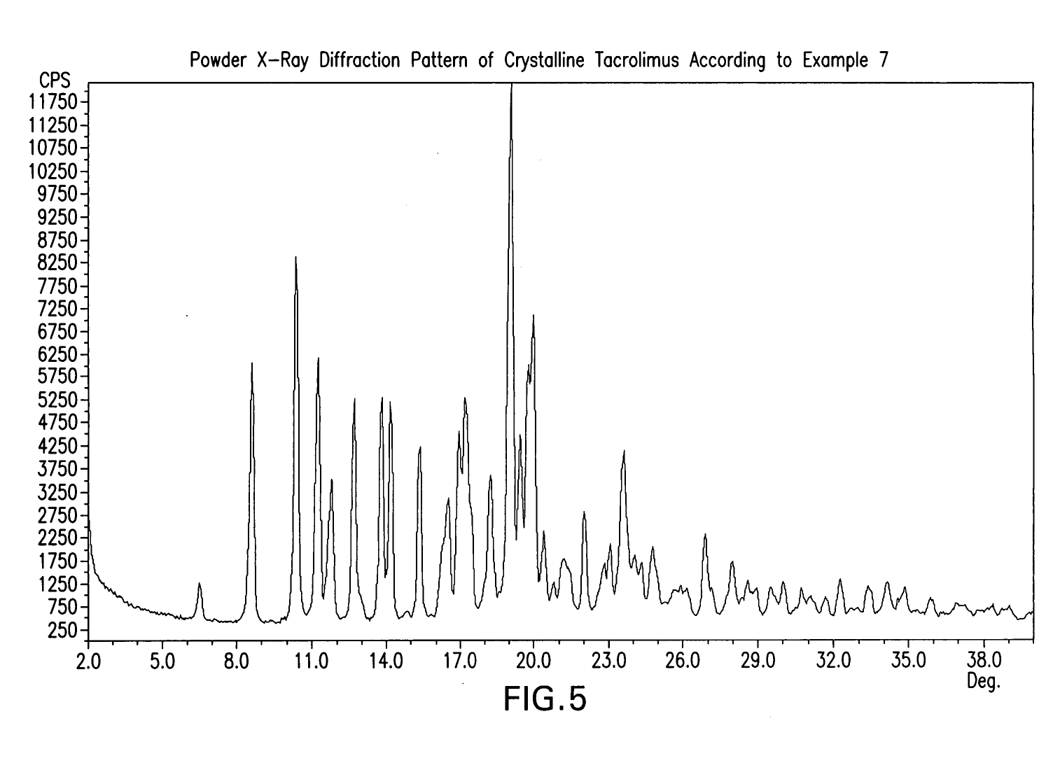

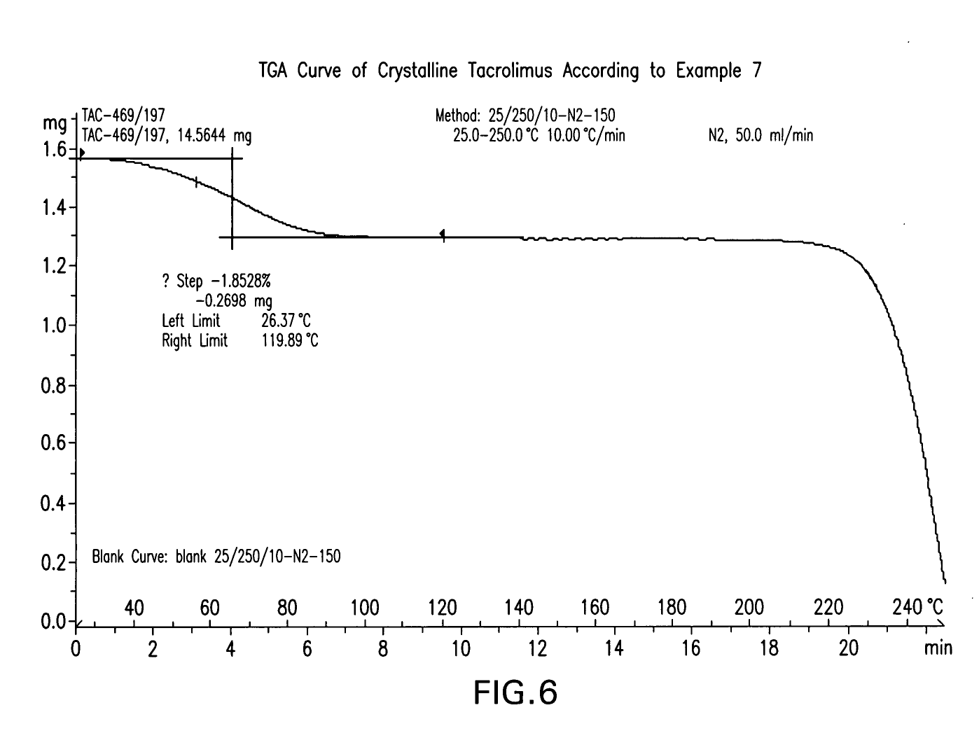

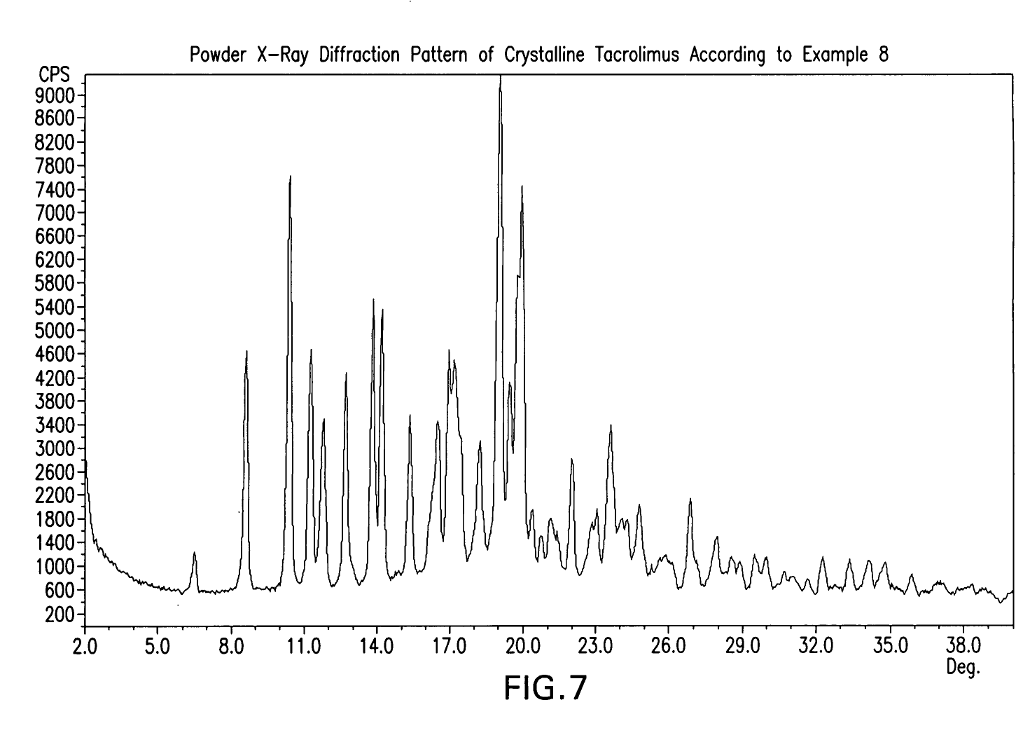

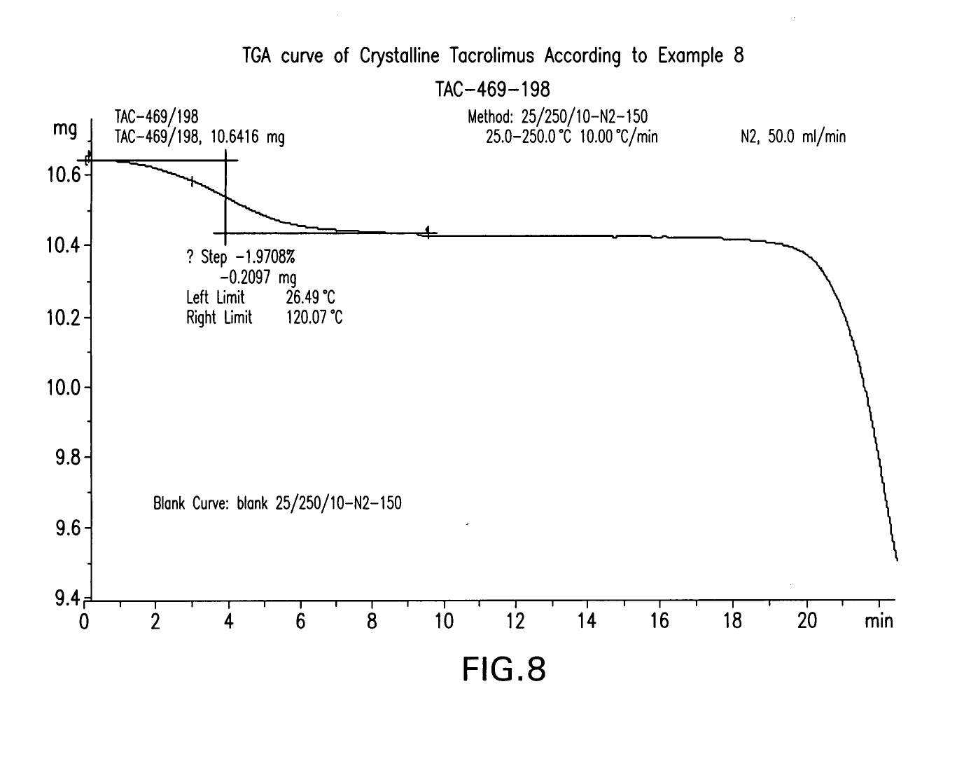

The crystalline form may be further characterized by TGA, showing a weight loss of about 1.9-2.2% at the temperature range of up to 120° C. The TGA curves of the crystalline form of tacrolimus are substantially depicted in FIGS. 5, 6, 7, and 8.

The particle size distribution (PSD) of the active ingredient is one of the key parameters of a formulation. The new crystalline form of Tacrolimus of the invention has a preferred maximum particle size of 500 μm. Preferably, the particle size is less than 300 μm, less than 200 μm, less than 100 μm, or even less than 50 μm.

For measuring particle size the following main methods are employed: sieves, sedimentation, electrozone sensing (coulter counter), microscopy, Low Angle Laser Light Scattering (LALLS).

The crystalline form of the present invention used to prepare pharmaceutical formulations may be substantially pure with respect to other crystalline forms, i.e., the novel forms contain less than about 10%, preferably less than about 5%, and even more preferably less than about 1% (by weight) of other crystalline forms of Tacrolimus. In certain embodiments, the novel crystalline forms contain less than about 10%, preferably less than about 5%, and even more preferably less than about 1% (by weight) of amorphous Tacrolimus.

Another embodiment of the present invention is a pharmaceutical formulation comprising a therapeutically effective amount of crystalline form of tacrolimus characterized by powder X-ray diffraction having peaks at about 10.5, 11.3 and 13.8±0.2 degrees 2θ, and an amount of pharmaceutically acceptable excipient.

“Therapeutically effective amount” means the amount of a crystalline form that, when administered to a patient for treating a disease or other undesirable medical condition, is sufficient to have a beneficial effect with respect to that disease or condition. The “therapeutically effective amount” will vary depending on the crystalline form, the disease or condition and its severity, and the age, weight, etc., of the patient to be treated. Determining the therapeutically effective amount of a given crystalline form is within the ordinary skill of the art, and requires no more than routine experimentation.

Pharmaceutical formulations of the present invention contain crystalline form of tacrolimus characterized by powder X-ray diffraction having peaks at about 10.5, 11.3 and 13.8±0.2 degrees 2θ. In addition to the active ingredient(s), the pharmaceutical formulations of the present invention may contain one or more excipients. Excipients are added to the formulation for a variety of purposes.

Diluents may be added to the formulations of the present invention. Diluents increase the bulk of a solid pharmaceutical composition, and may make a pharmaceutical dosage form containing the composition easier for the patient and caregiver to handle. Diluents for solid compositions include, for example, microcrystalline cellulose (e.g., AVICEL®), microfine cellulose, lactose, starch, pregelatinized starch, calcium carbonate, calcium sulfate, sugar, dextrates, dextrin, dextrose, dibasic calcium phosphate dihydrate, tribasic calcium phosphate, kaolin, magnesium carbonate, magnesium oxide, maltodextrin, mannitol, polymethacrylates (e.g., EUDRAGIT®), potassium chloride, powdered cellulose, sodium chloride, sorbitol, and talc.

Solid pharmaceutical compositions that are compacted into a dosage form, such as a tablet, may include excipients whose functions include helping to bind the active ingredient and other excipients together after compression. Binders for solid pharmaceutical compositions include acacia, alginic acid, carbomer (e.g., carbopol), carboxymethylcellulose sodium, dextrin, ethyl cellulose, gelatin, guar gum, hydrogenated vegetable oil, hydroxyethyl cellulose, hydroxypropyl cellulose (e.g., KLUCEL®), hydroxypropyl methyl cellulose (e.g., METHOCEL®), liquid glucose, magnesium aluminum silicate, maltodextrin, methylcellulose, polymethacrylates, povidone (e.g., KOLLIDON®, PLASDONE®), pregelatinized starch, sodium alginate, and starch.

The dissolution rate of a compacted solid pharmaceutical composition in the patient's stomach may be increased by the addition of a disintegrant to the composition. Disintegrants include alginic acid, carboxymethylcellulose calcium, carboxymethylcellulose sodium (e.g., AC-DI-SOL®, PRIMELLOSE®), colloidal silicon dioxide, croscarmellose sodium, crospovidone (e.g., KOLLIDON®, POLYPLASDONE®), guar gum, magnesium aluminum silicate, methyl cellulose, microcrystalline cellulose, polacrilin potassium, powdered cellulose, pregelatinized starch, sodium alginate, sodium starch glycolate (e.g., EXPLOTAB®), and starch.

Glidants can be added to improve the flowability of a non-compacted solid composition, and to improve the accuracy of dosing. Excipients that may function as glidants include colloidal silicon dioxide, magnesium trisilicate, powdered cellulose, starch, talc, and tribasic calcium phosphate.

When a dosage form such as a tablet is made by the compaction of a powdered composition, the composition is subjected to pressure from a punch and dye. Some excipients and active ingredients have a tendency to adhere to the surfaces of the punch and dye, which can cause the product to have pitting and other surface irregularities. A lubricant can be added to the composition to reduce adhesion, and ease the release of the product from the dye. Lubricants include magnesium stearate, calcium stearate, glyceryl monostearate, glyceryl palmitostearate, hydrogenated castor oil, hydrogenated vegetable oil, mineral oil, polyethylene glycol, sodium benzoate, sodium lauryl sulfate, sodium stearyl fumarate, stearic acid, talc, and zinc stearate.

Flavoring agents and flavor enhancers make the dosage form more palatable to the patient. Common flavoring agents and flavor enhancers for pharmaceutical products that may be included in the composition of the present invention include maltol, vanillin, ethyl vanillin, menthol, citric acid, fumaric acid, ethyl maltol, and tartaric acid.

Solid and liquid compositions may also be dyed using any pharmaceutically acceptable colorant to improve their appearance, and/or facilitate patient identification of the product and unit dosage level.

In liquid pharmaceutical compositions, the crystalline form of tacrolimus characterized by powder X-ray diffraction having peaks at about 10.5, 11.3 and 13.8±0.2 degrees 2θand any other solid excipients are dissolved or suspended in a liquid carrier such as water, vegetable oil, alcohol, polyethylene glycol, propylene glycol or glycerin.

Liquid pharmaceutical compositions may contain emulsifying agents to disperse uniformly throughout the composition an active ingredient or other excipient that is not soluble in the liquid carrier. Emulsifying agents that may be useful in liquid compositions of the present invention include, for example, gelatin, egg yolk, casein, cholesterol, acacia, tragacanth, chondrus, pectin, methyl cellulose, carbomer, cetostearyl alcohol, and cetyl alcohol.

Liquid pharmaceutical compositions may also contain a viscosity enhancing agent to improve the mouth-feel of the product and/or coat the lining of the gastrointestinal tract. Such agents include acacia, alginic acid bentonite, carbomer, carboxymethylcellulose calcium or sodium, cetostearyl alcohol, methyl cellulose, ethylcellulose, gelatin guar gum, hydroxyethyl cellulose, hydroxypropyl cellulose, hydroxypropyl methyl cellulose, maltodextrin, polyvinyl alcohol, povidone, propylene carbonate, propylene glycol alginate, sodium alginate, sodium starch glycolate, starch tragacanth, and xanthan gum.

Sweetening agents such as sorbitol, saccharin, sodium saccharin, sucrose, aspartame, fructose, mannitol, and invert sugar may be added to improve the taste.

Preservatives and chelating agents such as alcohol, sodium benzoate, butylated hydroxyl toluene, butylated hydroxyanisole, and ethylenediamine tetraacetic acid may be added at levels safe for ingestion to improve storage stability.

A liquid composition may also contain a buffer such as guconic acid, lactic acid, citric acid or acetic acid, sodium guconate, sodium lactate, sodium citrate, or sodium acetate. Selection of excipients and the amounts used may be readily determined by the formulation scientist based upon experience and consideration of standard procedures and reference works in the field.

The solid compositions of the present invention include powders, granulates, aggregates and compacted compositions. The dosages include dosages suitable for oral, buccal, rectal, parenteral (including subcutaneous, intramuscular, and intravenous), inhalant, and ophthalmic administration. Although the most suitable administration in any given case will depend on the nature and severity of the condition being treated, the most preferred route of the present invention is oral. The dosages may be conveniently presented in unit dosage form, and prepared by any of the methods well-known in the pharmaceutical arts.

Dosage forms include solid dosage forms like tablets, powders, capsules, suppositories, sachets, troches, and lozenges, as well as liquid syrups, suspensions, and elixirs.

The oral dosage form of the present invention is preferably in the form of an oral capsule having a dosage of about 10 mg to about 160 mg, more preferably from about 20 mg to about 80 mg, and most preferably capsules of 20, 40, 60, and 80 mg. Daily dosages may include 1, 2, or more capsules per day.

The dosage form of the present invention may be a capsule containing the composition, preferably a powdered or granulated solid composition of the invention, within either a hard or soft shell. The shell may be made from gelatin, and, optionally, contain a plasticizer such as glycerin and sorbitol, and an opacifying agent or colorant.

A composition for tableting or capsule filling may be prepared by wet granulation. In wet granulation, some or all of the active ingredients and excipients in powder form are blended, and then further mixed in the presence of a liquid, typically water, that causes the powders to clump into granules. The granulate is screened and/or milled, dried, and then screened and/or milled to the desired particle size. The granulate may then be tableted, or other excipients may be added prior to tableting, such as a glidant and/or a lubricant.

A tableting composition may be prepared conventionally by dry blending. For example, the blended composition of the actives and excipients may be compacted into a slug or a sheet, and then comminuted into compacted granules. The compacted granules may subsequently be compressed into a tablet.

As an alternative to dry granulation, a blended composition may be compressed directly into a compacted dosage form using direct compression techniques. Direct compression produces a more uniform tablet without granules. Excipients that are particularly well suited for direct compression tableting include microcrystalline cellulose, spray dried lactose, dicalcium phosphate dihydrate, and colloidal silica. The proper use of these and other excipients in direct compression tableting is known to those in the art with experience and skill in particular formulation challenges of direct compression tableting.

A capsule filling of the present invention may comprise any of the aforementioned blends and granulates that were described with reference to tableting, however, they are not subjected to a final tableting step.

The active ingredient and excipients may be formulated into compositions and dosage forms according to methods known in the art.

Having described the invention with reference to certain preferred embodiments, other embodiments will become apparent to one skilled in the art from consideration of the specification. The invention is further defined by reference to the following examples describing in detail the preparation of the composition and methods of use of the invention. It will be apparent to those skilled in the art that many modifications, both to materials and methods, may be practiced without departing from the scope of the invention.

The present invention, in certain of its embodiments, is illustrated by the following non-limiting examples.

### EXAMPLE 1

Extraction

Fermentation broth (22.2 m³) containing tacrolimus (3.42 kg) was extracted with 6.4 m³ iso-butyl acetate at pH between 9.0-9.5. The iso-butyl acetate solution was washed with water at pH between 6.0-8.0. The washed iso-butyl acetate phase was concentrated to oily-like residue under reduced pressure at temperature between 40°-45° C.

The oily-like residue was dissolved with iso-butyl acetate to a volume of 31 l. This concentrate was diluted with 167.5 l methanol and 18.6 l water. The water methanol solution was washed with 139.6 l n-Hexane. The water-methanol phase was concentrated under reduced pressure to volume of 44 l, and the concentrate was diluted with 44 l water.

The obtained mixture was extracted with 88 L ethyl acetate. The ethyl acetate extract was concentrated to volume of 22.4 l.

Crystallization:

This concentrate of ethyl acetate extract was combined with 158.4 l 0.1 M aqueous triethyl amine solution and with 67.3 l n-Hexane. The mixture was stirred at 20°-25° C. for 3 hours. The mixture was let to stand at 0°-25° C. for 48 hours (1 minute stirring every hour).

The crystals formed were isolated by filtration and were suspended first in 83 l 0.1 M aqueous triethyl amine solution and, second, in 83 l n-Hexane. The crystals were isolated by filtration.

The crystals were dried at 40° C. under reduced pressure. The dried crude tacrolimus had an assay 83%. Crude product contains 1.9 kg tacrolimus.

The yield of the crystallization step was 91%.

### EXAMPLE 2

In the following example, a macrolide (tacrolimus), as an oily concentrate from whole-broth extraction of macrolide-containing biomatter, was combined with polar solvent, hydrocarbon solvent, and water containing a base. The combination was held at a crystallization temperature for a total crystallization time. At the end of the total crystallization time, the crystalline macrolide was isolated. The proportions of components, the process variables, and the results are collected in Table I.

TABLE I

| Number of | | | Tacrolimus | | Polar | Hydrocarbon | | Total | | | |
|---|---|---|---|---|---|---|---|---|---|---|---|
| experiment | Concentrate | | content | | solvent | solvent | Water | t_{C} (hr) | T_{C} (° C.) | Yield | Assay |
| 1 | 15.23 | g | 1.42 | g | Ethyl acetate | n-Hexane | 0.1 N NaOH | 24 | +50-+20 | 41.82% | 84.65% |
| | | | | | 30.3 ml | 60.7 ml | 273 ml | | | | |
| 2 | 14.36 | g | 1.42 | g | Ethyl acetate | n-Hexane | 0.1 N NaOH | 20 | +25-0 | 78.48% | 81.68% |
| | | | | | 12.3 ml | 73.7 ml | 172 ml | | | | |
| 3 | 13.67 | g | 1.42 | g | Ethyl acetate | n-Hexane | 0.1 N NaOH | 20 | +25-0 | 79.06% | 81.74% |
| | | | | | 7.5 ml | 74.5 ml | 164 ml | | | | |
| 4 | 12.35 | g | 1.42 | g | Ethyl acetate | n-Hexane | 0.1 N NaOH | 11 | +20-−10 | 82.8% | 82.85% |
| | | | | | 10.6 ml | 63.4 ml | 148 ml | | | | |
| 5 | 11.47 | g | 1.42 | g | Ethyl acetate | n-Hexane | 0.1 N NH₃ | 62 | +25-0 | 79.19% | 82.55% |
| | | | | | 9.8 ml | 59 ml | 137.6 ml | | | | |
| 6 | 11.72 | g | 1.42 | g | Ethyl acetate | n-Hexane | 0.1 N NH₃ | 62 | +25-0 | 82.84% | 79.20% |
| | | | | | 6.4 ml | 63.9 ml | 140.64 ml | | | | |
| 7 | 12.17 | g | 1.42 | g | Ethyl acetate | n-Hexane | 0.1 N (C₂H₅)₃N | 62 | +25-0 | 85.76% | 85.03% |
| | | | | | 10.4 ml | 62.6 ml | 144.2 ml | | | | |
| 8 | 12.94 | g | 1.42 | g | Ethyl acetate | Cyclohexane | 0.1 N (C₂H₅)₃N | 62 | +25-0 | 82.98% | 82.18% |
| | | | | | 7 ml | 70.6 ml | 155.3 ml | | | | |
| 9 | 13.28 | g | 1.42 | g | Ethyl acetate | n-Hexane | 0.1 N (C₂H₅)₃N | 50 | +25-0 | 72.84% | 75.64% |
| | | | | | 11.4 ml | 68.3 ml | 159.4 ml | | | | |
| 10 | 14.72 | g | 1.42 | g | Ethyl acetate | n-Hexane | 0.1 N (C₂H₅)₃N | 32 | +25-0 | 74.74% | 84.81% |
| | | | | | 12.6 ml | 75.8 ml | 176 ml | | | | |
| 11 | 11.36 | g | 1.42 | g | Ethyl acetate | n-Hexane | 0.1 N (C₂H₅)₃N | 50 | +25-0 | 71.64% | 80.89% |
| | | | | | 9.7 ml | 58.4 ml | 136.3 ml | | | | |
| 12 | 11.39 | g | 1.42 | g | Ethyl acetate | n-Hexane | 0.1 N (C₂H₅)₃N | 50 | +25-0 | 88.32% | 83.68% |
| | | | | | 9.8 ml | 58.6 ml | 136.7 ml | | | | |
| 13 | 20.93 | g | 2.23 | g | Ethyl acetate | n-Hexane | 0.1 N (C₂H₅)₃N | 62 | +25-0 | 91.2% | 86.49% |
| | | | | | 17.9 ml | 107.8 ml | 251.2 ml | | | | |
| 14 | 20.17 | g | 2.23 | g | Ethyl acetate | n-Hexane | 0.1 N (C₂H₅)₃N | 62 | +25-0 | 62.7% | 83.34% |
| | | | | | 17.3 ml | 103.7 ml | 242 ml | | | | |
| 15 | 19.15 | g | 2.23 | g | Ethyl acetate | n-Hexane | 0.1 N (C₂H₅)₃N | 62 | +25-0 | 91.2% | 88.05% |
| | | | | | 16.4 ml | 98.5 ml | 229.8 ml | | | | |
| 16 | 20.4 | g | 2.23 | g | Ethyl acetate | n-Hexane | 0.1 N (C₂H₅)₃N | 62 | +25-0 | 91.2% | 88.06% |
| | | | | | 8.7 ml | 52.5 ml | 122.4 ml | | | | |
| 17 | 18.78 | g | 2.23 | g | Ethyl acetate | n-Hexane | 0.1 N (C₂H₅)₃N | 62 | +25-0 | 86.64% | 86.90% |
| | | | | | 4 ml | 24.2 ml | 56 ml | | | | |
| 18 | 4.56 | g | 0.557 | g | Acetonitrile | n-Hexane | 0.1 N (C₂H₅)₃N | 18 | +25-+20 | 79.92% | 83.46% |
| | | | | | 3.9 ml | 23.45 ml | 54.7 ml | | | | |
| 19 | 4.62 | g | 0.557 | g | n-Butanol | n-Hexane | 0.1 N (C₂H₅)₃N | 18 | +25-+15 | 63.12% | 88.72% |
| | | | | | 3.96 ml | 23.76 ml | 55.44 ml | | | | |
| 20 | 4.58 | g | 0.557 | g | Acetone | n-Hexane | 0.1 N (C₂H₅)₃N | 18 | +30-+20 | 87.07% | 82.56% |
| | | | | | 3.93 ml | 23.55 ml | 54.96 ml | | | | |
| 21 | 4.62 | g | 0.557 | g | Isobutanol | n-Hexane | 0.1 N (C₂H₅)₃N | 18 | +25-+10 | 67.34% | 89.78% |
| | | | | | 3.75 ml | 22.5 ml | 52.44 ml | | | | |
| 22 | 4.84 | g | 0.557 | g | Isopropanol | n-Hexane | 0.1 N (C₂H₅)₃N | 18 | +25-+20 | 80.26% | 83% |
| | | | | | 4.15 ml | 24.9 ml | 58.08 ml | | | | |
| 23 | 4.54 | g | 0.557 | g | Ethanol | n-Hexane | 0.1 N (C₂H₅)₃N | 18 | +35-+20 | 76.92% | 82.13% |
| | | | | | 3.89 ml | 23.35 ml | 54.48 ml | | | | |
| 24 | 4.43 | g | 0.525 | g | n-Propanol | n-Hexane | 0.1 N (C₂H₅)₃N | 18 | +25-+15 | 75.6% | 84.79% |
| | | | | | 3.79 ml | 22.78 ml | 53.16 ml | | | | |
| 25 | 4.34 | g | 0.525 | g | Methanol | n-Hexane | 0.1 N (C₂H₅)₃N | 18 | +25-+20 | 77.16% | 78.18% |
| | | | | | 3.72 ml | 22.32 ml | 52.08 ml | | | | |
| 26 | 3.84 | g | 0.525 | g | Diisopropyl | n-Hexane | 0.1 N (C₂H₅)₃N | 18 | +25-+10 | 59.52% | 72.35% |
| | | | | | ether | 19.74 ml | 52.08 ml | | | | |
| | | | | | 3.29 ml | | | | | | |

### EXAMPLE 3

Fermentation broth containing ascomycin was processed according to Example 1. The process resulted in 60% yield for crude ascomycin.

### EXAMPLE 4

Extraction:

Fermentation broth (22.2 m³) containing tacrolimus (3.42 kg) was extracted with 6.4 m³ iso-butyl acetate at pH between 9.0-9.5. The iso-butyl acetate solution was washed with water at pH between 6.0-8.0. The washed iso-butyl acetate phase was concentrated to oily-like residue under reduced pressure at temperature between 40-45° C.

The oily-like residue was dissolved with iso-butyl acetate to a volume of 31 l. This concentrate was diluted with 167.5 l methanol and 18.6 l water. The water-methanol solution was washed with 139.6 l n-Hexane. The water-methanol phase was concentrated under reduced pressure to volume of 44 l, and the concentrate was diluted with 44 l water.

The obtained mixture was extracted with 88 l ethyl acetate. The ethyl acetate extract was concentrated to volume of 22.4 l.

Crystallization:

This concentrate of ethyl acetate extract was combined with 158.4 l 0.1 M aqueous triethyl amine solution and with 67.3 l n-Hexane. The mixture was stirred at 20°-25° C. for 3 hours. The mixture was let to stand at 0°-25° C. for 48 hours (1 min stirring every hour).

The crystals formed were isolated by filtration and were suspended first in 83 l 0,1 M aqueous triethyl amine solution and, second, in 83 l n-Hexane. The crystals were isolated by filtration.

The crystals were dried at 40° C. under reduced pressure. The dried crude tacrolimus had an assay 83%. Crude product contains 1.9 kg tacrolimus crystalline form characterized by powder X-ray diffraction having peaks at about 10.5, 11.3 and 13.8±0.2 degrees 2θ.

The yield of the crystallization step was 91%.

### EXAMPLE 5

In the following example, a macrolide (tacrolimus), as an oily concentrate from whole-broth extraction of macrolide-containing biomatter, was combined with polar solvent, hydrocarbon solvent, and water containing a base. The combination was held at a crystallization temperature for a total crystallization time. At the end of the total crystallization time, the crystalline macrolide was isolated. The crystalline macrolide was a crystalline form of tacrolimus characterized by powder X-ray diffraction having peaks at about 10.5, 11.3 and 13.8±0.2 degrees 2θ.The proportions of components, the process variables, and the results are collected in Table I.

### EXAMPLE 6

Crystalline Tacrolimus (13 g) was dissolved in ethyl acetate (39 ml) and evaporated to dryness. This process was repeated twice. The evaporated oily or foamy material was dissolved in ethyl acetate (13 ml). Cyclohexane (78 ml) was added to the solution. Water (0.28 ml) was added in small portions during 3 hours. The mixture was stirred for an hour at room temperature. The crystalline product was filtered and washed with cyclohexane (13 ml) and dried for 16 hours at 40° C. under reduced pressure. Tacrolimus crystalline form characterized by powder X-ray diffraction having peaks at about 10.5, 11.3 and 13.8±0.2 degrees 2θ (9.49 g) was obtained.

### EXAMPLE 7

Tacrolimus (2 g) was dissolved in ethyl acetate (6 ml) and evaporated to dryness. This process was repeated twice. The evaporated oily material was dissolved in ethyl acetate (2 ml). Cyclohexane (10 ml) and dimethyl formamide (0.088 ml) were added to the solution and it was crystallized for 16 hours at 0-5° C. The crystalline product was filtered and washed with cyclohexane (6 ml) and dried for 5 hours at 50° C. under reduced pressure. Tacrolimus crystalline form characterized by powder X-ray diffraction having peaks at about 10.5, 11.3 and 13.8±0.2 degrees 2θ (1.28 g) was obtained.

### EXAMPLE 8

Tacrolimus (2 g) was dissolved in ethyl acetate (6 ml) and evaporated to dryness. This process was repeated twice. The evaporated oily material was dissolved in ethyl acetate (2 ml). Cyclohexane (12 ml) and dimethyl sulfoxide (0.044 ml) were added to the solution and it was stirred for 16 hours at 0-5° C. The crystalline product thus formed was filtered and washed with cyclohexane (6 ml) and dried for 5 hours at 50° C. under reduced pressure. Tacrolimus crystalline form characterized by powder X-ray diffraction having peaks at about 10.5, 11.3 and 13.8±0.2 degrees 2θ (1.57 g) was obtained.

### EXAMPLE 9

Tacrolimus (2 g) was dissolved in ethyl acetate (6 ml) and evaporated to dryness. This process was repeated twice. The evaporated oily material was dissolved in ethyl acetate (2 ml). Cyclohexane (12 ml) and a mixture of dimethyl formamide (0.044 ml) and water (0.022 ml) were added to the solution. The mixture was stirred for 16 hours at room temperature. The crystalline product thus formed was filtered and washed with cyclohexane (6 ml) and dried for 5 hours at 50° C. under reduced pressure. Tacrolimus crystalline form characterized by powder X-ray diffraction having peaks at about 10.5, 11.3 and 13.8±0.2 degrees 2θ (1.11 g) was obtained.

What is claimed:

1. Crystalline Tacrolimus.

2. A crystalline form of tacrolimus characterized by a powder X-ray diffraction pattern, having peaks at about 10.5, 11.3 and 13.8±0.2 degrees 2θ.

3. The crystalline form of claim 2, wherein the crystalline form is further characterized by an XRD peak at about 14.2±0.2 degrees 2θ.

4. The crystalline form of claim 3, wherein the crystalline form is further characterized by XRD peaks at about 8.7, 15.4 and 19.1±0.2 degrees 2θ.

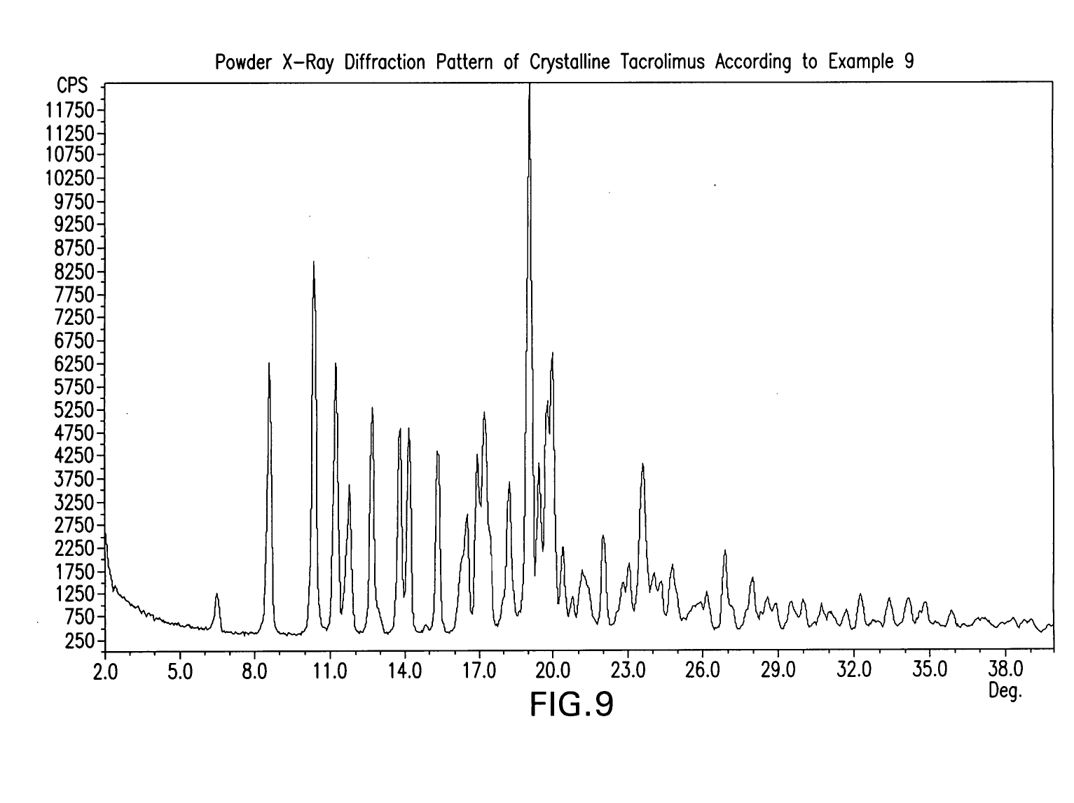

5. The crystalline form of claim 4, further characterized by a powder X-ray diffraction pattern, substantially as depicted in any of FIGS. 1, 2, 3, 5, 7, and 9.

6. The crystalline form of claim 2, wherein the crystalline form is characterized by a TGA, showing a weight loss of about 1.9-2.2% over a temperature range of up to 120° C.

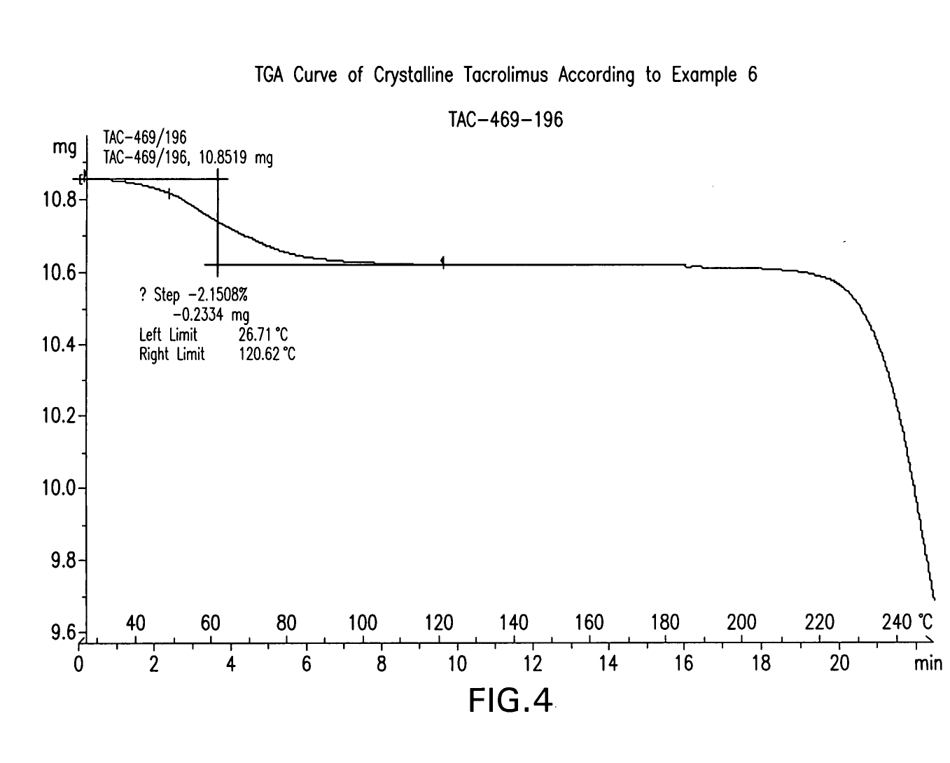

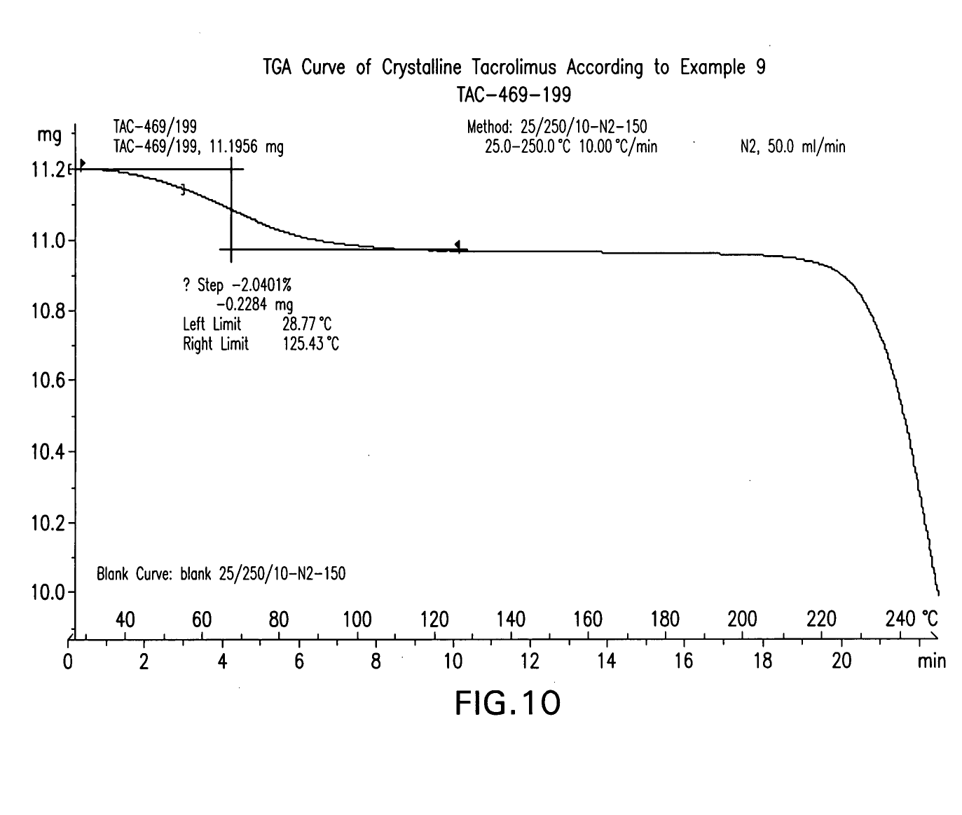

7. The crystalline form of claim 6, further characterized by TGA curves substantially as depicted in FIGS. 4, 6, 8, and 10.

8. The crystalline form of claim 2, wherein the crystalline form is monohydrate.

9. The crystalline form of claim 2, having a maximum particle size of 500 μm.

10. The crystalline form of claim 9, having a maximum particle size of 300 μm.

11. The crystalline form of claim 10, having a maximum particle size of less than 200 μm

12. The crystalline form of claim 11, having a maximum particle size of less than 100 μm.

13. The crystalline form of claim 12, having a maximum particle size of less than 50 μm.

14. The crystalline form of claim 2, wherein the crystalline form contains less than about 10% (by weight) of other crystalline or amorphous forms of Tacrolimus.

15. The crystalline form of claim 14, wherein the crystalline form contains less than about 5% (by weight) of other crystalline or amorphous forms of Tacrolimus.

16. The crystalline form of claim 15, wherein the crystalline form contains less than about 1% (by weight) of other crystalline or amorphous forms of Tacrolimus.

17. A method for crystallizing the crystalline form of tacrolimus of claim 2 from a tacrolimus starting material, comprising the steps of:
a) combining a tacrolimus starting material, a polar solvent, a hydrocarbon solvent, and water, whereby at least two phases are formed, at least one of which is a water-rich phase, and wherein the pH of the water-rich phase is at least about 7,
b) maintaining the combination at for at least 1 hour, whereby a tacrolimus-rich phase is formed from which the crystalline form of tacrolimus of claim 2 crystallizes.

18. The method of claim 17, further comprising the step of isolating the crystalline form of tacrolimus that crystallizes.

19. The method of claim 17, wherein the combination of step b) is maintained at a temperature of from about −15° C. to about 50° C.

20. The method of claim 19, wherein the combination of step b is maintained at a temperature of from about −5° C. to about 40° C.

21. The method of claim 20, wherein the combination of step b is maintained at a temperature of from about −2° C. to about 35° C.

22. The method of claim 17, wherein the combination of step b is maintained for between 48 and 100 hours.

23. The method of claim 17, wherein the polar solvent is selected from the group consisting of alcohols, esters, nitriles and ethers.

24. The method of claim 23, wherein the polar solvent is selected from the group consisting of ethyl acetate, acetonitrile, methanol, ethanol, n-propanol, iso-propanol, n-butanol, iso-butanol, acetone, diisopropyl ether, dimethyl formamide, and dimethyl acetamide.

25. The method of claim 24, wherein the polar solvent is ethyl acetate.

26. The method of claim 17, wherein the hydrocarbon solvent is selected from the group consisting of n-hexane, n-heptane, octane, iso-octane cyclohexane, methylcyclohexane, benzene, toluene, and xylene.

27. The method of claim 26, wherein the hydrocarbon solvent is n-hexane.

28. The method of claim 17, wherein the pH of the water-rich phase is about 8 or higher.

29. The method of claim 17, wherein the water comprises a base selected from NaOH, KOH, Ca(OH)₂, NH₃, Et₃N, diethylamine and pyridine.

30. A method of crystallizing the crystalline form of tacrolimus of claim 2 from a tacrolimus starting material comprising the steps of:
a) combining a concentrate residue from whole-broth extraction of tacrolimus-containing biomatter in a polar solvent with a hydrocarbon solvent, and water, whereby at least two phases are formed, at least one of which is a water-rich phase, and wherein the pH of the water-rich phase is at least about 7,
b) maintaining the combination at for at least 1 hour, whereby a tacrolimus-rich phase is formed from which the crystalline form of tacrolimus of claim 2 crystallizes.

31. The method of claim 30, further comprising the step of isolating the crystalline form of tacrolimus that crystallizes.

32. The method of claim 30, wherein the combination of step b is maintained at a temperature of from about −15° C. to about 50° C.

33. The method of claim 32, wherein the combination of step b is maintained at a temperature of from about −5° C. to about 40° C.

34. The method of claim 33, wherein the combination of step b is maintained at a temperature of from about −2° C. and about 35° C.

35. The method of claim 30, wherein the combination of step b is maintained for between 48 and 100 hours.

36. The method of claim 30, wherein the polar solvent is selected from the group consisting of alcohols, esters, nitrites and ethers.

37. The method of claim 36, wherein the polar solvent is selected from the group consisting of ethyl acetate, acetonitrile, methanol, ethanol, n-propanol, iso-propanol, n-butanol, iso-butanol, acetone, diisopropyl ether, dimethyl formamide, and dimethyl acetamide.

38. The method of claim 37, wherein the polar solvent is ethyl acetate.

39. The method of claim 30, wherein the hydrocarbon solvent is selected from the group consisting of n-hexane, n-heptane, octane, iso-octane cyclohexane, methylcyclohexane, benzene, toluene, and xylene.

40. The method of claim 39, wherein the hydrocarbon solvent is n-hexane.

41. The method of claim 30, wherein the pH of the water-rich phase is about 8 or higher.

42. The method of claim 30, wherein the water comprises a base selected from NaOH, KOH, Ca(OH)₂, NH₃, Et₃N, diethylamine and pyridine.

43. A method of crystallizing the crystalline form of tacrolimus of claim 2 from a tacrolimus starting material comprising the steps of:
a) combining, at a temperature of about 20° to about 25° C., tacrolimus starting material, ethyl acetate, n-hexane, and a water solution of a base selected from the group consisting of NaOH, KOH, Ca(OH)₂, NH₃, (C₂H₅)₃N, diethylamine and pyridine, whereby at least two phases are formed, one of which is a water-rich phase, wherein the pH of the water-rich phase is greater than about 7,
b) maintaining the combination at a temperature of about 20° C. to about 25° C. for at least 1 hour, whereby a tacrolimus-rich phase is formed from which the crystalline form of tacrolimus of claim 2 crystallizes,
c) maintaining the combination at a temperature of about 0° C. to about 20° C. for at least 1 hour, and
d) recovering the crystalline form of tacrolimus of claim 2 that crystallizes.

44. The method of claim 43, wherein the pH of the water-rich phase is about 8 or higher.

45. A method of crystallizing the crystalline form of tacrolimus of claim 2 from a tacrolimus starting material comprising the steps of:
a) combining, at a temperature of about 20° to about 25° C., a concentrate residue from whole-broth extraction of tacrolimus-containing biomatter in ethyl acetate, n-hexane, and a water solution of a base selected from NaOH, KOH, Ca(OH)₂, NH₃, (C₂H₅)₃N, diethylamine and pyridine whereby at least two phases are formed, one of which is a water-rich phase, wherein the pH of the water-rich phase is greater than about 7,
b) maintaining the combination at a temperature of about 20° C. to about 25° C. for at least 1 hour, whereby a tacrolimus-rich phase is formed from which the crystalline form of tacrolimus of claim 2 crystallizes,
c) maintaining the combination at a temperature of about 0° C. to about 20° C. for at least 1 hour, and
d) recovering the crystalline form of tacrolimus of claim 2 that crystallizes.

46. The method of claim 45, wherein the pH of the water-rich phase is about 8 or higher.

47. In a method for crystallizing the crystalline form of tacrolimus of claim 2 from a tacrolimus starting material, the step of combining the tacrolimus starting material, a polar solvent, a hydrocarbon solvent, and water, whereby at least two phases are formed, at least one of which is water rich, wherein the pH of the water-rich phase is at least about 7.

48. In a method for crystallizing the crystalline form of tacrolimus of claim 2 from a concentrate residue from whole-broth extraction of tacrolimus-containing biomatter in a polar solvent, the step of combining the tacrolimus concentrate in the polar solvent, a hydrocarbon solvent, and water, whereby at least two phases are formed, at least one of which is water rich, wherein the pH of the water-rich phase is at least about 7.
